(19) United States
(12) Patent Application Publication
(10) Pub. No.: US 2013/0001610 A1
(43) Pub. Date: Jan. 3, 2013

(54) DISPLAY APPARATUS

(75) Inventors: Yasushi Iwakura, Funabashi-shi (JP); Kohei Nagayama, Chiba-shi (JP); Kiyofumi Sakaguchi, Miura-gun (JP); Atsushi Shiozaki, Mobara-shi (JP); Noriyuki Shikina, Ichihara-shi (JP)

(73) Assignee: CANON KABUSHIKI KAISHA, Tokyo (JP)

(21) Appl. No.: 13/583,913

(22) PCT Filed: Mar. 14, 2011
(86) PCT No.: PCT/JP2011/001475

§ 371 Date: Sep. 10, 2012

(30) Foreign Application Priority Data
Mar. 24, 2010 (JP) 2010-068284

(51) Int. Cl. H01L 33/08

(52) U.S. Cl. 257/91; 257/E33.06

(57) ABSTRACT

In a display apparatus in which light from a light-emitting element is extracted by an optical element, a difference in reflection characteristics between a display area including the optical element corresponding to the light-emitting element and a non-display area including no optical element impairs the appearance of the display apparatus.

Optical elements are uniformly disposed in a display area and a non-display area of a display apparatus.

### TECHNICAL FIELD

The present invention relates to a display apparatus including an electroluminescent element.

### BACKGROUND ART

In display apparatuses including an organic EL element (a light-emitting element including an organic light-emitting layer), in order to increase the desired luminance, the voltage applied to electrodes is increased to increase the electric current passing through the organic EL element. However, this method has problems of increased power consumption and a reduced life of the organic EL element. In order to solve these problems, PTL 1 proposes a display apparatus sealed with a moisture-proof film in which a microlens is disposed on an organic EL element to improve light extraction efficiency.

FIG. 4 is a cross-sectional view of a top-emission-type display apparatus described in PTL 1. The display apparatus includes a microlens 13 for each organic EL element 11 on a light extraction side of the organic EL elements 11 in a display area 1a. Light from the organic EL element 11 is condensed through the microlens 13 and is extracted to the outside. Thus, light can be efficiently extracted to the outside, achieving high luminance.

The surface of a display apparatus reflects light incident on the display apparatus from the outside (extraneous light). An observer therefore visually recognizes light extracted from the display apparatus together with extraneous light reflected from the surface of the display apparatus. For example, even when the display apparatus displays black, reflected light increases luminance, and black cannot be visually recognized as black. This causes deterioration in display quality, such as a low contrast.

As in the display apparatus illustrated in FIG. 4, reflection of extraneous light will be discussed below for the case where a microlens is disposed for each of the organic EL elements 11, that is, microlenses are disposed only in the display area. Extraneous light incident on the display apparatus is mostly specularly reflected in a non-display area 1b without microlenses. However, in the display area including the microlenses, extraneous light incident on the display apparatus is not only specularly reflected but also scatteringly reflected by the curved surface of each of the microlenses. Thus, the display area 1a appears more whitish than the non-display area to an observer, resulting in visual recognition of a boundary between the display area and the non-display area. Hence, there is a problem that the display surface of the display apparatus has a poor appearance.

In general, in order to reduce extraneous light reflection, a circularly polarizing plate is disposed on a light extraction side of a display apparatus. However, the circularly polarizing plate can absorb specularly reflected light but cannot absorb light having a disordered polarization state reflected via diffuse reflection. Thus, light specularly reflected in the non-display area can be absorbed by the circularly polarizing plate, but light having a disordered polarization state scattered on the curved surface of the microlens 13 is not absorbed by and passes through the circularly polarizing plate. Even when the display apparatus illustrated in FIG. 4 is provided with the circularly polarizing plate, therefore, a boundary between the display area and the non-display area remains. Thus, the problem of poor appearance of the display surface of the display apparatus cannot be solved.

### CITATION LIST

### Patent Literature

PTL 1: Japanese Patent Laid-Open No. 2004-39500

### SUMMARY OF INVENTION

In order to solve the problems described above, the present invention provides a display apparatus that includes

a plurality of light-emitting elements disposed on a substrate, and

an optical element corresponding to each of the light-emitting elements, the optical element being disposed on a light extraction side of each of the light-emitting elements,

wherein the optical elements are disposed in both a display area and a non-display area.

In the present specification, an area on a display surface that can display images in accordance with image data from the outside is referred to as a display area, and an area that cannot display images is referred to as a non-display area. The embodiments described below include an example in which no light-emitting element is disposed in the non-display area. It is obvious that an embodiment in which a light-emitting element disposed in the non-display area does not emit light is also included in the definition of the non-display area.

### ADVANTAGEOUS EFFECTS OF INVENTION

A display apparatus according to one aspect of the present invention uniformly includes optical elements 13 in a display area 1a and a non-display area 1b. Thus, the luminance of extraneous light reflected from a display surface is substantially uniform in the display area 1a and the non-display area 1b. Consequently, a boundary between the display area and the non-display area cannot be visually recognized, thereby achieving an excellent appearance of the display apparatus.

### BRIEF DESCRIPTION OF DRAWINGS

FIG. 1 is a schematic view of a display apparatus according to a first embodiment and Example 1.

FIG. 2 is a schematic view of a display apparatus according to a second embodiment and Example 3.

FIG. 3 is a schematic view of a display apparatus according to a first embodiment and Example 2.

FIG. 4 is a schematic view of a display apparatus according to related art.

### DESCRIPTION OF EMBODIMENTS

Embodiments of the present invention will be described below with reference to the drawings. Like parts are designated by like reference numerals throughout these drawings and will not be described again. The light-emitting element, as used herein, refers to an element that can emit light by the application of an electric potential in accordance with image data. Although an organic EL element is described below as an example of the light-emitting element, various other electroluminescent elements, such as inorganic EL elements, may be used.

### First Embodiment

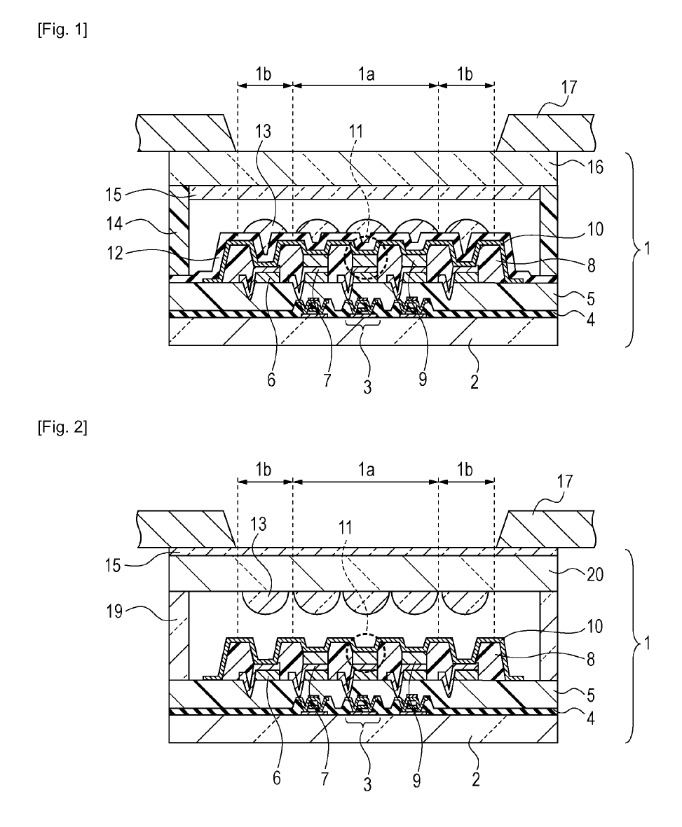

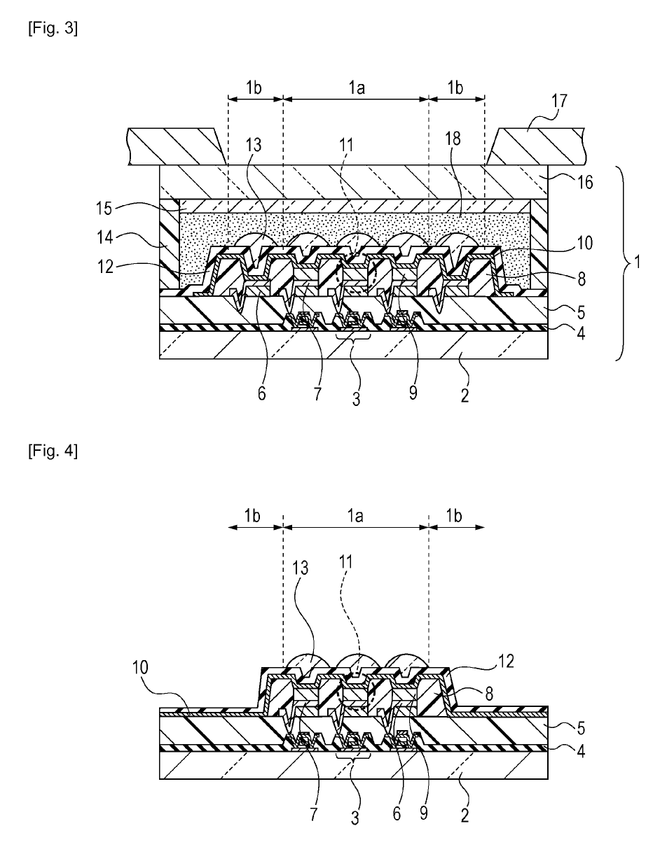

FIG. 1 is a schematic cross-sectional view of a display apparatus 1 according to a first embodiment. The display apparatus 1 is a top-emission-type display apparatus sealed with a protective film 12 (film sealing). The display apparatus 1 is provided with a housing 17 to ensure adequate strength or installation on another electronic device or the like. Thus, a display surface within the housing 17 is viewable to users.

Pixel circuits 3 for driving organic EL elements 11 and peripheral circuitry (not shown) for driving the pixel circuits 3 are disposed on a first substrate 2. These circuits are covered with an insulating layer 4. The first substrate 2 may be an insulating substrate having a low permeability to water or gas, such as oxygen, for example, a glass substrate or a resin substrate coated with silicon nitride. The insulating layer 4 may be a layer having high insulating properties, such as a silicon nitride layer or a silicon oxide layer. The circuits include thin-film transistors (TFTs) containing a semi-conductor, such as polycrystalline silicon or amorphous silicon, and wiring. A planarization layer 5 is disposed on the insulating layer 4 to flatten the asperities due to the circuits. The planarization layer 5 may be formed of a photosensitive organic material, such as a polyimide resin or an acrylic resin.

A plurality of organic EL elements 11 are disposed on the planarization layer 5 in the display area 1a. Each of the organic EL elements 11 includes a first electrode 7, an organic compound layer 9, and a second electrode 10 stacked in this order. If necessary, a bank 8 may be disposed between adjacent organic EL elements 11 to separate emission regions. The material of the second electrode 10 may be a material having high transparency in a visible wavelength region and a low electrical resistance, such as indium tin oxide (ITO), indium zinc oxide, or thin-film silver. The first electrodes 7 may be formed of the same material as the second electrode 10. The organic compound layer 9 may include a light-emitting layer and another functional layer, such as an electron-injection layer, an electron-transport layer, a hole-injection layer, or a hole-transport layer. The organic compound layer 9 may be formed of known materials appropriately combined. The banks 8 may be formed of the same organic material as the planarization layer 5.

In the display area 1a, each of the first electrodes 7 is electrically connected to the corresponding pixel circuit 3 via a contact hole disposed in the planarization layer 5 and the insulating layer 4. An electric current is supplied to the organic EL elements 11 through the pixel circuits 3 in accordance with image data.

In the present embodiment, in order to extract light travelling from the organic compound layer 9 to the first substrate 2 from the front side (opposite the first substrate 2), a reflective layer 6 is disposed between the first electrode 7 and the planarization layer 5. The reflective layers 6 may be formed of a metal having high reflectance, such as silver, aluminum, magnesium, silicon, or chromium, or an alloy mainly composed of any of these metals. The reflective layers 6 may also be a dielectric multilayer film, for example, formed of an oxide or a fluoride, such as TiO3, SiO2, Nb2O5, Ta2O5, CaF2, or MgF2.

The non-display area 1b may have any structure, including the structure of the display area 1a. For example, the reflective layers 6 in the display area 1a may also be disposed in the non-display area 1b, and the banks in the display area 1a may also be disposed in the non-display area 1b. A higher degree of structural similarity between the non-display area 1b and the display area 1a can reduce the difference in extraneous light reflection characteristics and consequently make the boundary less noticeable. In FIG. 1, as in the display area 1a, the non-display area 1b includes the planarization layer 5, the reflective layers 6, the first electrodes 7, the second electrode 10, and the banks 8. The non-display area 1b may further include the organic compound layers 9. These constitute elements having the same structure as the light-emitting elements (hereinafter referred to as dummy light-emitting elements) in the non-display area 1b. However, these dummy light-emitting elements are not electrically connected to the pixel circuits 3. Thus, the dummy light-emitting elements are not supplied with electric currents in accordance with image data and cannot display images.

In order to prevent deterioration of the organic EL elements 11 caused by water intrusion from outside the display apparatus, the display area 1a and the non-display area 1b are covered with the protective layer 12. The protective layer 12 may be a film having high transmittance in a visible wavelength region, less defects, and low gas permeability. The protective layer 12 may be formed of silicon nitride, silicon oxide, or silicon oxynitride. Although the protective layer 12 is a monolayer in FIG. 1, the protective layer 12 may be a multilayer composed of the same or different layers. For example, the protective layer 12 may be a multilayer composed of inorganic films or a multilayer composed of at least one inorganic film and at least one organic film.

The optical elements 13 corresponding to the organic EL elements 11 are disposed on the protective layer 12. The optical elements 13 are uniformly disposed in the display area 1a and the non-display area 1b, that is, over the entire display surface. Although the optical elements 13 are convex lenses in FIG. 1, the optical elements 13 are not limited to the convex lenses. The optical elements 13 can control the traveling direction and the intensity of light from the organic EL elements 11. The optical elements 13 may be optical elements utilizing the refraction of light, such as convex lenses, concave lenses, prisms, Fresnel lenses, or GRIN lenses, or optical elements utilizing the diffraction of light, such as diffraction grating or holography.

Each of the optical elements 13 may correspond to one of the organic EL elements 11 or a plurality of organic EL elements 11. The former structure can easily increase light extraction efficiency. The condensation characteristics of the optical elements 13 can be controlled in consideration of the luminous area of the organic EL elements 11 and the distance between the light-emitting surface and the optical elements 13. The extraction efficiency increases with a decrease in the distance between the organic EL elements 11 and the optical elements 13. Thus, the optical elements 13 may be disposed on the protective layer 12, as illustrated in FIG. 1. Furthermore, the optical elements 13 may be disposed in any position on the light extraction side of the organic EL elements 11. In the case that the protective layer 12 is composed of an inorganic layer/an organic layer/an inorganic layer, the organic layer between the inorganic layers may have a function of the optical element. This can reduce the number of materials and the material cost.

A circularly polarizing plate 15 and a second substrate 16 are disposed on top of the optical elements 13. The second substrate 16 protects the organic EL elements 11 and the optical elements 13 on the first substrate 2 against external forces or contamination. The second substrate 16 may be a substrate having high light transmittance in a visible wavelength region and great rigidity, such as a glass sheet or an acryl sheet. The circularly polarizing plate 15 includes a linear polarizer and a ¼ phase shifter. Use of a film including a plurality of ¼ phase shifters layered for light having different phase shifts and angles of direction of an optical axis can reduce incident light having different wavelengths. The circularly polarizing plate 15 may include a known linear polarizer and a known ¼ phase shifter in combination. The circularly polarizing plate 15 may be omitted, although the circularly polarizing plate 15 can reduce the reflection of extraneous light and improve display quality.

The circularly polarizing plate 15 is bonded to the surface of the second substrate 16. The circularly polarizing plate 15 may be bonded to either surface of the second substrate 16 provided that the ¼ phase shifter is closer to the organic EL elements 11 than the linear polarizer. In FIG. 1, the first substrate 2 is bonded to the second substrate 16 with a binder 14 in the surrounding area, forming a space between the first substrate 2 and the second substrate 16. As illustrated in FIG. 3, the space between the first substrate 2 and the second substrate 16 may be filled with a transparent material (filler) 18. Such a structure can reinforce the display surface of the display apparatus against external forces. In addition, such a structure can reduce reflection by the interface between the hollow portion and the optical elements 13 and the interface between the hollow portion and the circularly polarizing plate 15, thereby reducing extraneous light reflection. In the case that the optical elements 13 utilize refraction of light, a refractive index difference between the optical elements 13 and the filler 18 is required. To this end, a combination of the material of the optical elements 13 and the material of the filler 18 may be appropriately selected, or a layer for refracting light may be disposed between the optical elements 13 and the filler 18. If the filler 18 has a function of the binder 14, the binder 14 may be omitted.

In the case that the optical elements 13 are convex lenses, the refractive index of the optical elements 13 may be 0.1 or more higher than the refractive index of the filler 18. In the case that the refractive index of the filler 18 is higher than the refractive index of the optical elements 13, the optical elements 13 are concave lenses, the concave sides of which face the filler.

Although a detailed method for manufacturing a display apparatus is not described, a known method may be used.

### Second Embodiment

A second embodiment will be described below with reference to FIG. 2. The present embodiment is different from the first embodiment in the sealing structure. The structural components up to the second electrode 10 are the same as in the first embodiment and will not be further described.

The organic EL elements 11 that include components up to the second electrode 10 are sealed with a sealing substrate 20. The sealing substrate 20 not only prevents the intrusion of extraneous water into the organic EL elements 11 but also functions as the second substrate 16 described in the first embodiment. The sealing substrate 20 is bonded via a sealing member 19 to the first substrate 2 on which the components up to the second electrode 10 are formed. In addition to the conditions required for the second substrate 16 in FIG. 1, the sealing substrate 20 should have a low permeability to water or gas, such as oxygen. The sealing substrate 20 may be a glass substrate or a resin substrate covered with a film having a low gas permeability, such as a silicon oxide film or a silicon nitride film. The sealing member 19 also should have a low gas permeability to prevent intrusion of extraneous water or the like via the sealing member 19. Examples of the material of the sealing member 19 include, but are not limited to, epoxy resins, silicon resins, low-melting glasses, and low-melting metals. The sealed space in FIG. 2 is a vacuum or is filled with an inert gas, such as argon or nitrogen. The sealed space may be filled with a filler, such as a transparent resin having a low water content. The filler filling the sealed space should have a different refractive index from the optical elements 13, as described in the first embodiment.

In the first embodiment, the optical elements 13 are directly disposed on the organic EL elements 11 covered with the protective film 12. This is because the optical elements 13 are provided after the organic EL elements 11 are covered with the protective film 12 to prevent the intrusion of extraneous water or the like. In the present embodiment, a member for preventing the intrusion of extraneous water or the like into the organic EL elements 11 is not provided before sealing with the sealing substrate 20. Thus, during the process of forming the optical elements 13, extraneous water or the like intruding into the organic EL elements 11 may cause the deterioration of the organic EL elements 11. It is therefore difficult to provide the optical elements 13 directly on the organic EL elements 11. Thus, in the present embodiment, the optical elements 13 are provided on the surface of the sealing substrate 20 facing the first substrate 2. The sealing substrate 20 is then bonded to the first substrate 2. The amount of light passing through the lenses increases with a decrease in the distance between the optical elements 13 and the organic EL elements 11. Thus, the optical elements 13 may be provided on the surface of the sealing substrate 20 facing the organic EL elements 11. Although the circularly polarizing plate 15 is provided on the light extraction side of the sealing substrate 20 in FIG. 2, the circularly polarizing plate 15 may be provided between the sealing substrate 20 and the optical elements 13 or may be omitted.

The embodiments of the present invention described above are provided for illustrative purposes only, and various modifications may be made in the present invention without departing from the gist of the present invention. For example, although an active-matrix electroluminescent display apparatus is described above, the present invention may be applied to a passive-matrix display apparatus.

### EXAMPLES

### Example 1

A method for manufacturing a display apparatus according to Example 1 will be described below with reference to FIG. 1.

### Process 1: Formation of TFT and Insulating Layer

Polycrystalline silicon TFTs, pixel circuits 3, and peripheral circuitry were formed on a first substrate 2 made of glass. The surface of the first substrate 2 on which the circuits were formed was covered with a silicon nitride film (insulating layer) 4. The pixel circuits 3, the peripheral circuitry, and the silicon nitride film 4 were formed by a known CVD, laser annealing, and/or patterning method. The pixel circuits 3 were electrically connected to a power supply terminal (not shown) via wiring. In the present example, the first electrodes 7 electrically connected to the pixel circuits were anodes, and the second electrode 10 was a cathode.

Process 2: Formation of Planarization Layer

The circuits and the insulating layer 4 were covered with a film serving as the planarization layer 5. The film serving as the planarization layer 5 was formed by applying an oligomer material by a spin coating method to the first substrate 2 subjected to the process 1 and subsequently firing and curing the oligomer material. After the firing and curing of the oligomer material, the resulting planarization layer 5 was washed with water and was heated at 180 degrees Celsius for two hours for dehydration treatment. Contact holes were then formed in the planarization layer 5 and the insulating layer 4. First, a photoresist layer having a thickness of 1 micrometer was formed on the planarization layer 5 by a spin coating method. The photoresist was patterned by exposure and development such that portions corresponding to the contact holes were opened. Portions of the planarization layer 5 and the insulating layer 4 within the openings of the photoresist layer were removed by a reactive ion etching (RIE) method using the patterned photoresist layer as a mask to form the contact holes. The photoresist layer was then removed. Contact holes for electrically connecting the pixel circuits 3 to the first electrodes 7 were formed in the display area 1a. Simultaneously, a contact hole (a contact hole for the cathode) for electrically connecting the second electrode 10 to wiring connected to a ground terminal was formed on the outside of the display area 1a.

### Process 3: Formation of Light Reflection Layer and First Electrode

After the contact holes were formed, the reflective layers 6 corresponding to the organic EL elements 11 were formed outside the contact holes. Essentially, the reflective layers 6 are only provided for the corresponding organic EL elements 11. In the present example, however, the reflective layers 6 were also formed in the non-display area 1b in which no organic EL element was to be formed. A metal layer having a thickness of 100 nm was formed from an aluminum-silicon alloy by a sputtering method. The metal layer was patterned to form the reflective layers 6 in the same manner as in the process 2 except that a wet etching method was used. An ITO layer having a thickness of 140 nm serving as the first electrodes 7 was then formed by a sputtering method on the surface of the first substrate 2 on which components up to the reflective layers 6 were formed. The ITO layer was pattern such that the ITO layers remained on the reflective layers 6 and the contact holes. The first electrodes 7 had a shape corresponding to the organic EL elements 11 and were electrically connected to the pixel circuits.

### Process 4: Formation of Bank

A polyimide resin layer having a thickness of 1.6 micrometers was formed on the planarization layer 5 and the first electrode 7 by a spin coating method. The polyimide resin layer was then patterned in the same manner as in the process 2 to form the banks 8. The banks 8 had portions in which the organic EL elements 11 were to be formed, that is, openings corresponding to emission regions. The banks 8 define the region in which the organic EL elements 11 are to be formed and are therefore essentially unnecessary in the non-display area 1b. In the present example, however, like the display area 1a, the banks 8 were also formed in the non-display area 1b in which no organic EL element was to be formed.

### Process 5: Formation of Organic Compound Layer Containing Light-Emitting Layer

The organic compound layers 9 each containing a light-emitting layer were formed by a vapor deposition method. First, a hole-transport layer having the following chemical formula (1) was formed on each of the first electrodes 7.

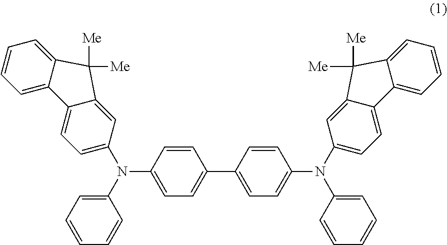 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

Next, an organic light-emitting layer that can emit blue light was formed by coevaporation of a compound having the following chemical formula (2) serving as a host and a compound having the following chemical formula (3) serving as a dopant.

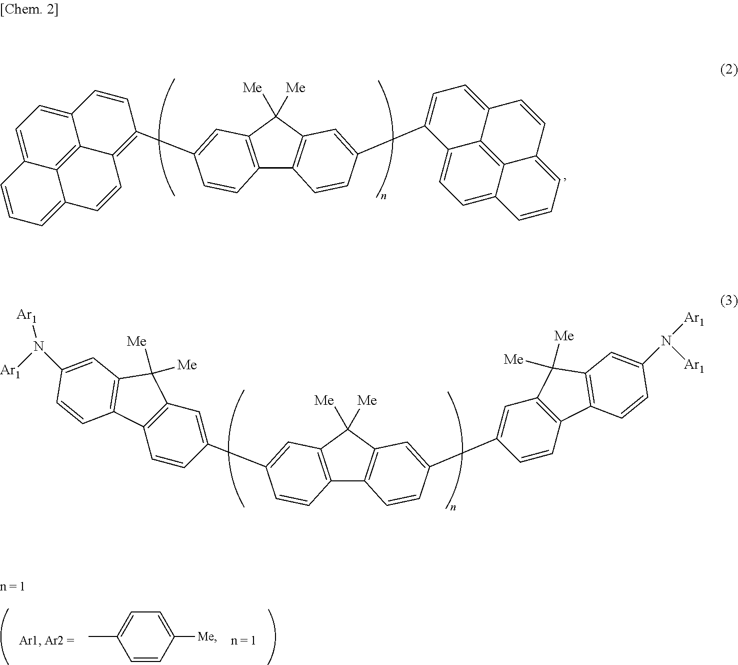

An electron-transport layer made of 2,9-bis[2-(9,9′-dimethylfluorenyl)]-1,10-phenanthroline was then formed on the organic light-emitting layer by a vapor deposition method. An electron-injection layer was then formed by co-evaporation of Al and Li. Thus, the organic compound layers 9 each containing the light-emitting layer were formed in which the hole-transport layer, the light-emitting layer, the electron-transport layer, and the electron-injection layer were stacked in this order. After the organic compound layers 9 were formed, the first substrate 2 was stored in a nitrogen atmosphere at a dew point of −80 degrees Celsius before the formation of the protective layer 12 to prevent the intrusion of water or the like into the organic compound layers 9.

In the present example, the plurality of organic EL elements 11 include a single organic light-emitting layer. The materials of the organic light-emitting layer may be changed from one organic EL element 11 to another using a mask. In this case, the organic EL elements 11 can display different colors, achieving multi-color display. For example, the organic EL elements 11 that can display the three primary colors of light (red, green, and blue) can achieve full-color display.

### Process 6: Formation of Second Electrode

An indium zinc oxide was formed on the organic compound layer 9 as the second electrode 10 by a sputtering method. The second electrode 10 was a common electrode for the organic EL elements 11 and was also formed on the region in which the contact hole for the cathode was disposed.

Process 7: Formation of Protective Layer

A silicon nitride film serving as the protective layer 12 was formed in the display area 1a and the non-display area 1b by VHF plasma CVD. First, the first substrate 2 on which the components up to the second electrode 10 were formed was placed in a film-forming apparatus. After the internal pressure of the film-forming chamber was reduced to the order of 1×10−3 Pa, 20 sccm of silane gas, 1000 sccm of nitrogen gas, and 1000 sccm of hydrogen gas were supplied to the film-forming chamber. The reaction space pressure was adjusted to 100 Pa. Next, a 60 MHz high-frequency power of 400 W was supplied to radio-frequency electrodes to form the silicon nitride film having a thickness of 1000 nm on the second electrode 10. After the protective layer 12 was formed, the protective layer 12, which is an insulating layer, was removed from the surfaces of the power supply terminal and the ground terminal.

### Process 8: Formation of Optical Element on Protective Layer

A mask having circular openings having the same pitch as the organic EL elements 11 was placed on the first substrate 2 on which the components up to the protective layer 12 were formed. The openings of the mask were aligned with the corresponding emission regions of the organic EL elements 11. The openings of the mask were provided in not only the display area in which the organic EL elements 11 were disposed but also the non-display area. A photosensitive acrylic resin having a viscosity of 1000 P (25 degrees Celsius) was printed on the protective layer 12 through the mask. The resin immediately after printing assumed a cylindrical shape having a diameter of 30 micrometers and a thickness of 5 micrometers. The first substrate 2 on which the resin was printed was placed on a metal base having heating and cooling functions. When the first substrate 2 was heated to 80 degrees Celsius, the viscosity of the printed resin decreased, and the shape of the resin changed from cylindrical to hemispherical by the action of surface tension. After the first substrate 2 was slowly cooled to room temperature, the hemispherical resin was cured by ultraviolet irradiation to form convex lenses (optical elements) 13. The convex lenses were uniformly formed in the display area and the non-display area. The convex lenses 13 had a diameter of 32 micrometers, a height of 8 micrometers, a curvature radius of 16 micrometers, and a refractive index nD of 1.68.

### Process 9: Bonding Between First Substrate and Second Substrate

After the circularly polarizing plate 15 was bonded to one surface of the second substrate 16, the binder 14 made of an ultraviolet-curable epoxy resin was applied to the outer edge on the surface of the first substrate 2 on which the organic EL elements 11 were formed. The surface of the first substrate 2 to which the binder was applied was attached to the surface of the second substrate 16 to which the circularly polarizing plate 15 was bonded. The thickness of the binder 14 was adjusted such that the surfaces of the convex lenses 13 were not in contact with the circularly polarizing plate 15. A spacer may be used to retain such a distance. The binder 14 was cured by ultraviolet irradiation from the side of the second substrate 16, thereby bonding the second substrate 16 to the first substrate 2. Thus, the display apparatus 1 was completed.

### Example 2

A display apparatus was fabricated in the same manner as in Example 1 except that a space between the convex lenses (optical elements) 13 and the circularly polarizing plate 15 was filled with the filler 18. The processes up to the process 8 were as described in Example 1. The subsequent process will be described below with reference to FIG. 3.

### Process 9-2: Bonding Between First Substrate and Second Substrate

The binder 14 made of an ultraviolet-curable epoxy resin was applied to the outer edge on the surface of the first substrate 2 on which the organic EL elements 11 were formed. The filler 18 was applied to a region surrounded by the binder 14 on the first substrate 2. The filler 18 was a photocurable fluoropolymer. After the first substrate 2 and the second substrate 16 were placed under reduced pressure, the surface of the first substrate 2 to which the binder 14 and the filler 18 were applied was bonded to the second substrate 16. The binder 14 and the filler 18 were cured by ultraviolet irradiation from the side of the second substrate 16, thereby bonding the first substrate 2 to the second substrate 16. Thus, the display apparatus 1 was completed. The filler 18 thus cured had a refractive index nD of 1.39.

### Example 3

A display apparatus having a sealing structure including the sealing substrate 20 according to the second embodiment was fabricated. The processes up to the process 6 were as described in Example 1. The subsequent processes will be described below with reference to FIG. 2. In the present example, the protective layer 12 was not formed. Thus, after the organic compound layers 9 were formed, the first substrate 2 was stored in a nitrogen atmosphere at a dew point of −80 degrees Celsius until the organic EL elements 11 were sealed with the sealing substrate (second substrate) 20.

### Process 7-3: Formation of Optical Element on Second Substrate

A mask having circular openings as described in the process 8 in Example 1 was placed on the sealing substrate 20 having substantially the same size as the first substrate 2. The mask openings on the sealing substrate 20 were aligned with the organic EL elements 11 on the first substrate 2 in advance. The hemispherical convex lenses (optical elements) 13 were formed on the sealing substrate 20 in an area corresponding to the display area 1a and the non-display area 1b on the first substrate 2 in the same manner as in the process 8 in Example 1.

### Process 8-3: Bonding Between First Substrate and Sealing Substrate (Second Substrate)

The sealing member 19 made of low-melting glass was applied to the edge on the surface of the first substrate 2 on which the organic EL elements 11 were formed. The sealing substrate 20 was annealed to sufficiently remove water and was then placed in the nitrogen atmosphere in which the first substrate 2 was placed. The surface of the first substrate 2 on which the sealing member 19 was formed was attached to the surface of the sealing substrate 20 on which the optical elements 13 were formed while the emission regions of the organic EL elements 11 were aligned with the corresponding optical elements 13. The sealing member 19 was melted by YAG laser irradiation from the side of the sealing substrate 20 and was then cooled to seal the organic EL elements 11.

### Process 9-3: Bonding of Circularly Polarizing Plate

The circularly polarizing plate 15 was bonded to a light extraction side of the sealing substrate 20, thus completing the display apparatus 1.

### Example 4

A display apparatus was fabricated in the same manner as in Example 1 except that the circularly polarizing plate 15 was omitted.

### Comparative Example 1

A display apparatus according to a comparative example of the present invention was fabricated in the same manner as in Example 1 except that the convex lenses 13 were not formed in the non-display area 1b.

### Comparative Example 2

A display apparatus according to a comparative example of the present invention was fabricated in the same manner as in Example 4 except that the convex lenses 13 were not formed in the non-display area 1b.

(Evaluation Results)

While no image was displayed, the display apparatuses according to Examples 1 to 3 and Comparative Examples 1 and 2 were visually examined for the boundary between the display area and the non-display area. Table 1 shows the results, in which “Excellent” indicates that no boundary was visually recognized and poor black reproduction was not noticeable, “Fair” indicates that no boundary was visually recognized but black appeared whitish, and “Poor” indicates that the boundary was visually recognized.

The results show that during no light emission the boundary between the display area 1a and the non-display area 1b was not visually recognized on the display surfaces of the display apparatuses according to Examples 1 to 4 and was visually recognized in the display apparatuses according to Comparative Examples 1 and 2. The display apparatus according to Example 2 seemed to exhibit slightly better black reproduction than the display apparatus according to Example 1. This is probably because the filler 18 filling the hollow portion eliminated the interfaces having a large refractive index difference between the hollow portion and the circularly polarizing plate 15 and between the hollow portion and the convex lenses 13, thereby reducing reflection.

These results show that display apparatuses according to the present invention have a uniform reflected light intensity on the display surface, no visually recognizable boundary between the display area and the non-display area, and excellent display surface appearances.

TABLE 1

| | Appearance of display surface |
|---|---|
| Example 1 | Excellent |
| Example 2 | Excellent |
| Example 3 | Excellent |
| Example 4 | Fair |
| Comparative example 1 | Poor |
| Comparative example 2 | Poor |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-068284, filed Mar. 24, 2010, which is hereby incorporated by reference herein in its entirety.

### REFERENCE SIGNS LIST

1 Display apparatus
1a Display area
1b Non-display area
2 First substrate
6 Reflective layer
11 Light-emitting element (organic EL element)
12 Protective layer
13 Optical element

1. A display apparatus comprising:
a plurality of light-emitting elements disposed on a substrate; and
an optical element corresponding to each of the light-emitting elements, the optical element being disposed on a light extraction side of each of the light-emitting elements,
wherein the optical elements are disposed uniformly in an area which is viewable to users as a display surface.

2. The display apparatus according to claim 1, further comprising a reflective layer opposite the light extraction side, wherein the reflective layer is disposed in an area which is viewable to users as a display surface.

3. The display apparatus according to claim 1, further comprising a bank in an area which is viewable to users as a display surface.

4. The display apparatus according to claim 1, wherein the optical elements are selected from convex lenses, concave lenses, prisms, Fresnel lenses, or GRIN lenses.

5. A display apparatus comprising:
a plurality of light-emitting elements disposed on a substrate;
an optical element corresponding to each of the light-emitting elements, the optical elements being disposed on a light extraction side of each of the light-emitting elements; and
a housing to ensure adequate strength or installation on an electronic device,
wherein the optical elements are disposed uniformly in an area within the housing.

6. The display apparatus according to claim 5, further comprising a reflective layer opposite the light extraction side, wherein the reflective layer is disposed in an area which is viewable to users as a display surface.

7. The display apparatus according to claim 5, further comprising a bank in an area which is viewable to users as a display surface.

8. The display apparatus according to claim 5, wherein the optical elements are selected from convex lenses, concave lenses, prisms, Fresnel lenses, or GRIN lenses.
